(19) United States
(12) Patent Application Publication
(10) Pub. No.: US 2005/0233551 A1
(43) Pub. Date: Oct. 20, 2005

(54) Method for depositing silicon by pulsed cathodic vacuum arc

(75) Inventors: Paul L. Bergstrom, Houghton, MI (US); Hui Xia, Houghton, MI (US)

Correspondence Address: MICHAEL BEST & FRIEDRICH, LLP, 100 E WISCONSIN AVENUE, MILWAUKEE, WI, 53202, US

(73) Assignee: Board of Control of Michigan Technological University, Houghton, MI (US)

(21) Appl. No.: 11/107,548

(22) Filed: Apr. 15, 2005

Related U.S. Application Data
(60) Provisional application No. 60/562,431, filed on Apr. 15, 2004.

(51) Int. Cl. C30B 1/00; H01L 21/20; H01L 21/36

(52) U.S. Cl. 438/478

(57) ABSTRACT

A method of depositing a silicon layer on a substrate includes the steps of placing a doped silicon (or silicon composite) target and a substrate in a vacuum chamber. An arc discharge is initiated using the silicon target as a cathode and the chamber as an anode to generate a plasma containing target material. Current pulses of a predetermined frequency are applied between the cathode and the anode and the arc is reinitiated as necessary so that silicon material from the plasma is deposited on the substrate to form a layer having a desired thickness. The resultant silicon layer is an important component in MEMS devices.

### CROSS REFERENCE TO OTHER APPLICATIONS

This application claims priority under 35 U.S.C. sec. 119 to provisional patent application No. 60/562,431, filed on Apr. 15, 2004, which is hereby incorporated by reference.

### FIELD OF THE INVENTION

The invention relates to the deposition of a silicon layer on a substrate by a pulsed cathodic vacuum arc process.

### BACKGROUND

Many devices and structures of micro-electromechanical systems (MEMS) include a silicon thin film layer, such as polycrystalline silicon (polysilicon). Polysilicon is often a first choice when selecting among materials for mechanical construction films, in large part because of its well-known mechanical properties, including a high mechanical strength as well as a high etch selectivity to various underlying thin films, and in particular, to an oxide layer. Further, known methods exist for depositing a polysilicon layer.

In particular, for MEMS devices and structures, polysilicon is typically deposited using silane and a chemical vapor deposition (CVD) technique, such as a low pressure chemical vapor deposition (LPCVD) process. The LPCVD process generally requires a further annealing step at high temperature to achieve well-controlled stress in the deposited thin film. However, the low deposition rate of the LPCVD process generally prohibits its commercial use for films thicker than approximately 5 microns. An improved CVD process for depositing polysilicon, called epipoly, can be performed in an epitaxial reactor on a seed layer of LPCVD polysilicon. This improved process has a higher deposition rate although the deposited polysilicon layer has a higher surface roughness and thus typically requires an additional polishing step.

Other CVD processes for depositing polysilicon are also known, such as plasma-enhanced chemical vapor deposition (PECVD), and hot-wire chemical vapor deposition (HWCVD). However, in general, these known CVD processes are disadvantageous due to their high cost and relatively high deposition temperature. Further, although PECVD allows for a lower deposition temperature, the deposition rate is typically only 6-12 nm/min. Additional concerns with the PECVD process include the conformability of the deposition and a high hydrogen content in the deposited polysilicon layer.

Physical vapor deposition (PVD), such as sputtering, is another choice for the deposition of a silicon thin film layer. The main advantages to a PVD process include a low deposition temperature and a low manufacturing cost. Further, sputtering is a mature process but the quality of a sputtered silicon layer is often limited by the low energy nature of the process.

The integration of MEMS devices and structures with each other and with other micro-systems often presents a challenge due to the high thermal sensitivities of devices and structures present in these micro-systems. For example, micro-electronic systems can include devices such as submicron complementary metal-oxide-semiconductor field-effect transistors (CMOS FETs), which include ultra-thin, precisely defined, ion implanted source and drain regions that are typically formed in initial fabrication steps. However, as described above, many of the known methods for depositing a polysilicon layer include high temperature processing steps. The CMOS source and drain regions, when exposed to high temperatures in later processing steps, become less defined, resulting in the potential degradation of device performance. Thus, process related temperature limitations often prohibit the post-CMOS integration of a wide range of possible MEMS devices and structures.

Cathodic vacuum arc deposition is a known low temperature process used to deposit various thin films or coatings, most commonly thin films of metal nitride, which is a wear resistant coating. As this technology has been refined, it has also been used to deposit various oxides, diamond-like carbon, and superconductors. Cathodic vacuum arc deposition involves placing a source material to be deposited and a substrate to be coated in an evacuated deposition chamber. The negative lead of a power supply is attached to the source material (referred to as the cathode) and the positive lead is attached to an anode, which can be the deposition chamber. The substrate to be coated is often at the same potential as the anode. An arc discharge is initiated, using, for example, an arc-initiating trigger that is at or near the same potential as the anode. Such a trigger contacts and then moves away from the cathode. When the trigger is in close proximity to the cathode, the difference in potential between the trigger and the cathode causes an arc of electricity to extend therebetween. As the trigger is moved further away, the arc jumps between the cathode and the anodic chamber. The exact point, or points, where an arc touches the surface of the cathode is referred to as a cathode spot. Absent a steering mechanism, a cathode spot will move randomly about the surface of the cathode. The energy deposited by the arc at a cathode spot is intense, such that cathode material at the cathode spot vaporizes into a plasma. Positive ions of the plasma are attracted to objects within the deposition chamber that have a negative electric potential. Some deposition processes maintain the substrate to be coated at the same electric potential as the anode, while others use a biasing source to lower the potential of the substrate and thereby make the substrate relatively more attractive to the positively charged ions. In either case, the substrate is coated with the vaporized material from the cathode.

This process is characterized by a low deposition temperature, a high deposition rate, and a relatively low operational cost. Further, it is a high-energy process due to the nature of the plasma discharge produced. Two approaches for controlling the arc include a direct current (DC) method and a pulsed current method. Compared with the DC method, the pulsed current method has the advantages of higher ion energies, a higher deposition rate, and a reduction in macro-droplets, or large drops of cathode material, that are intrinsically associated with the cathodic arc process. Known filters exist that operate to decrease the quantity of macro-droplets that reach the substrate.

Several issues have limited the use of a cathodic arc process for depositing a silicon thin film layer on a substrate. First, the low electric conductivity of intrinsic silicon means that an arc cannot be initiated thereon unless the silicon is heated to around 600 to 700° C. to substantially increase its electric conductivity. Another issue with silicon is its low thermal conductivity and brittleness compared with most metals. The local heating that occurs at cathode spots and the resulting thermal shock can cause a silicon cathode to easily crack during a cathodic arc process. Further, the mobility of a cathode spot on silicon is low.

Previous work relating to use of a cathodic vacuum arc deposition process for depositing thin films of silicon have only described the use of the DC method for controlling the arc. Researchers in England and Israel have independently succeeded in the operation of a continuous cathodic arc on a polycrystalline silicon cathode. For example, using a DC arc current from 30 to approximately 100 A, Bilek studied microstructures of the deposited silicon layer, and found that it can vary from completely amorphous to microcrystallines embedded in an amorphous matrix, depending on the substrate temperature and the magnitude of the negative bias voltage of the substrate. Further, Arbilly and Boxman prepared amorphous silicon thin films at low arc currents of 20-30 A and used the superposition of oppositely-directed magnetic fields from two coils to rotate the silicon cathode spots. They pointed out that good conductivity at room temperature of amorphous silicon films deposited by the DC cathodic arc process might be explained by a denser film structure with fewer dangling bonds as compared to films prepared by other processes.

However, the use of a pulsed current in a cathodic arc process for depositing a silicon thin film layer has not previously been described or suggested.

### SUMMARY OF THE INVENTION

A method of depositing a silicon layer on a substrate as a component in a micro-system, such as a structural layer in a MEMS device, is described. The method includes placing a doped silicon target and a substrate, such as a silicon or glass substrate, in a chamber. A vacuum is created in the chamber. An arc discharge is initiated using the silicon target as a cathode and the chamber as an anode to generate a plasma containing target material, wherein the plasma extends between the silicon target and the substrate. The arc discharge contacts the cathode at a cathode spot on the target, and the cathode spot changes location over time. Current pulses of a predetermined frequency are applied between the cathode and the anode, and the arc is reinitiated as necessary so that silicon material from the plasma is deposited on the substrate to form a layer having a desired thickness.

In another embodiment, a silicon composite layer is deposited on a substrate. The method includes placing a silicon composite target, such as a Si—Al composite, and a substrate, such as a silicon or glass substrate, in a chamber. A vacuum is created in the chamber. An arc discharge is initiated using the silicon composite target as a cathode and the chamber as an anode to generate a plasma at a cathode spot on the silicon composite target, wherein the plasma extends between the target and the substrate and the cathode spot changes location over time. Current pulses of a predetermined frequency are applied between the cathode and the anode, and the arc is reinitiated as necessary so that silicon material from the plasma is deposited on the substrate to form a silicon composite layer having a desired thickness.

### BRIEF DESCRIPTION OF THE DRAWINGS

FIG. 1 schematically illustrates a system for depositing a silicon or silicon composite layer on a substrate using a pulsed cathodic vacuum arc process;

FIG. 2 illustrates a typical waveform of the arc discharge during operation in the continuous pulsed mode;

FIGS. 3(a)-(d) illustrate cross-sectional SEM micrographs of the silicon films grown on a Si (111) wafer at different arc peak currents;

FIG. 4 illustrates an X-ray diffraction pattern of a silicon film sample deposited at an arc peak current of 100 A;

FIGS. 5(a) and (b) illustrate respective cross-sectional scanning electron microscope views of a deposited silicon thin film and a deposited silicon composite thin film; and

FIG. 6 illustrates a differential scanning calorimetry curve for a deposited silicon aluminum composite film.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

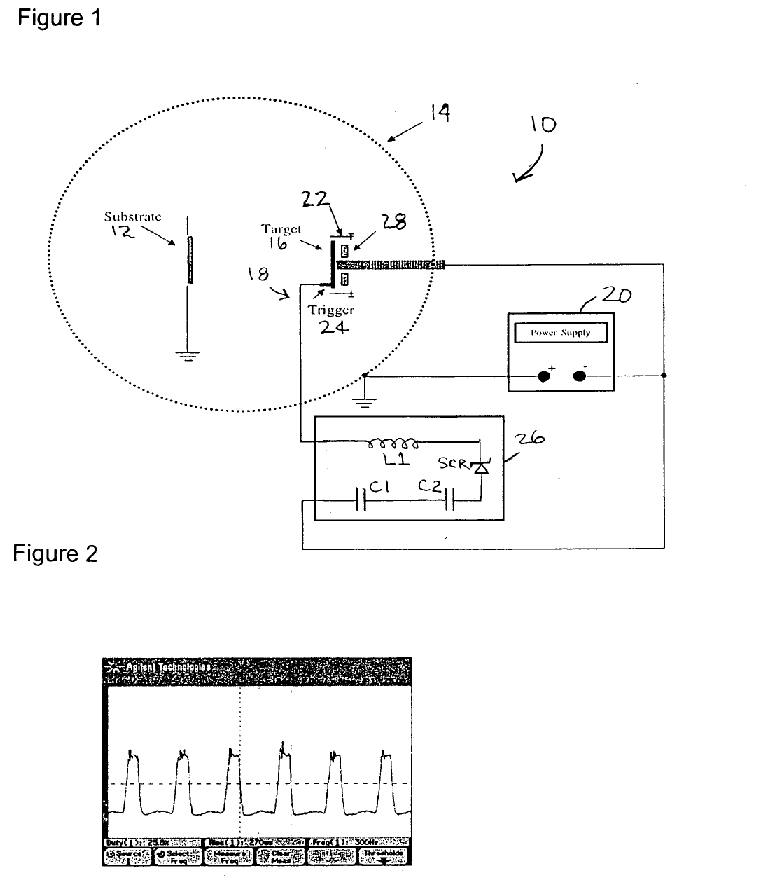

FIG. 1 schematically illustrates a system 10 for depositing a silicon thin film layer on a substrate 12 using a pulsed cathodic vacuum arc process. Such a silicon thin film is desirable as a component of a MEMS device or structure. For example, a silicon layer deposited by the pulsed cathodic vacuum arc process is particularly useful as a component of a MEMS device such as an inertial sensor, pressure sensor, or any silicon structure wherein the mechanical properties of the silicon layer are important because the silicon layer is ultimately suspended above another surface with one or more anchors (such as a cantilevered beam).

In one construction, the system 10 includes a chamber 14, a substrate holder (not shown) positioned in the chamber 14, a substrate 12 held in the substrate holder, and a target 16 (cathode) positioned in the chamber 14. The system 10 also includes an initiator 18 for initiating the arc, a power supply 20 connected across the target 16 and the chamber 14, a shield 22, a steering mechanism 28 for steering the cathode spot, and a cooling assembly (not shown) for controlling the temperature of the silicon target 16.

As a general overview, the process for depositing a silicon layer or a silicon composite layer includes the steps of positioning the silicon target 16 and the substrate 12 in the chamber 14, creating a vacuum in the chamber 14, and initiating an arc discharge using the target 16 as a cathode and the chamber 14 as an anode. A plasma including charged ions of the target (cathode) material is generated at the cathode spot where the arc contacts the target 16 and the plasma extends between the target 16 and the substrate 12. The steering mechanism 28 operates to move the cathode spot around on the target 16. Current pulses between the cathode and the anode are applied, preferably at a predetermined frequency, to deposit silicon material from the plasma on the substrate 12. In some embodiments, the current pulses are superimposed on a DC current component. A DC current component can sustain the arc, at least temporarily. Even with a DC current component, however, the arc eventually quenches, so the arc is re-initiated as necessary, and current pulses are further applied to deposit a layer of the cathode material on the substrate 12 to a desired thickness. When there is no DC current component, it is necessary to re-initiate the arc after each pulse.

More specifically with respect to the system 10, the chamber 14 is connected to the positive terminal of the power supply 20 and operates as the anode. The chamber 14 can be grounded and a vacuum can be created in the chamber. In one embodiment, the chamber is a cylindrical stainless steel chamber, 840 mm in diameter and 585 mm in length. A diffusion pump backed by a mechanical pump (neither pump shown) can be used to evacuate the chamber to a pressure below 4×10⁻⁴ Torr; and preferably below 1×10^{31 5} Torr.

The target 16 (cathode) is connected to the negative terminal of the power supply 20. In one construction, the target is bonded using indium to a copper backing plate (not shown) in the chamber 14. The copper backing plate is a component of the cooling assembly for water cooling the target 16. Further, in one construction, the target 16 is maintained at a temperature at or below approximately 15° C. during the deposition process.

In one embodiment, the target 16 is a highly doped, wafer-like, commercially available, silicon (Si) target that is 76 mm in diameter and 3 mm thick. Highly doped means that the silicon includes p- or n-type dopants at a concentration approximately in excess of 1×10²⁰ atoms/cm³. P-type dopants can be boron (B) or gallium (Ga), and n-type dopants can be phosphorus (P) or arsenic (As).

In another embodiment, the target 16 is a silicon composite. The silicon composite may include metal elements such as aluminum (Al) or titanium (Ti), or elements such as carbon (C). For example, a Si—Al composite or Si—Ti composite can be used as the target. Further, the target may be a silicide target including Ti, W, Mo, Co, T, or other refractory metals.

In particular, a composite having a ratio of 3:1 weight percentage of Si to Al can be used. Such a target can be produced by powder metallurgy, and is commercially available. Other ratios of Si to Al could also be used, such as a weight ratio of Si to Al that is greater than 50%, or more preferably, a weight ratio of Si to Al that is greater than 60%. One advantage to using a silicon composite target incorporating aluminum is that the cathode spot is much easier to control compared to using a highly doped silicon target.

The substrate holder can be made of stainless steel, and the substrate 12 can be clamped to the substrate holder, such that the substrate 12 is at a distance of approximately 170 mm from the target 16.

In one embodiment, the substrate 12 is a silicon wafer, perhaps lightly doped, while in other embodiments, other semiconductor substrates or a micro slide glass substrate can be used. For example, because the deposited silicon doped layer or deposited silicon composite layer as described herein can be a component layer in a MEMS or other micro-system device or structure, the substrate 12 can also be a silicon substrate having various other deposited thin film layers that may or may not be patterned. In particular, the surface of the substrate on which the silicon material is to be deposited may not be level.

In a preferred embodiment, the substrate 12 is grounded, although in other embodiments, a bias voltage can be applied to the substrate 12, as is known in the art. In one embodiment, the substrate is neither heated nor cooled 12, although the temperature of the substrate is monitored, and during the deposition, the temperature of the substrate remains at least below 500° C., and preferably below 400° C.

The initiator operates to initiate the arc discharge, which ultimately includes the plasma discharge of cathode material. Arc initiators are known in the art. In a preferred embodiment, the initiator includes a trigger 24 and a trigger circuit 26. The trigger 24 can be a graphite coated ceramic insulator tube that is supported by a spring loaded copper lead wire that keeps the trigger 24 in contact with the surface of the cathode. Arc initiation can then be achieved by applying a high voltage, such as 350 V, across the interface between the trigger 24 and the cathode using the trigger circuit 26. This method of arc initiation is based on rapid Joule heating and produces a graphitic or trigger plasma. This trigger plasma provides a sufficiently large current path to initiate the arc discharge from the cathode, which then results in a much larger current discharge with the generation of the ionized species from the surface of the cathode. Although the trigger 24 is initially coated with graphite, the graphite is not needed for arc initiation once the ceramic surface of the trigger is coated with silicon material after several uses of the trigger in the system. As more fully explained below, the trigger circuit 26 can be set to re-trigger the trigger as necessary.

The initiator 18 can be other devices, as other known ways exist to generate the arc discharge and plasma of cathode material. For example, a commonly used trigger for metal coating applications is a mechanical pin made of molybdenum or tungsten that momentarily grounds the cathode surface and draws back to generate the initial spark that ignites the arc discharge and generates the plasma.

As a further example, a pulsed laser trigger could be used to superheat a small location on the cathode while it is biased to generate an arc discharge and plasma directly from the surface of the cathode.

The shield 22 can be a cylindrical stainless steel shield around the outer edge of the target 16, with a spacing from the outer edge of the target of approximately 2-3 mm.

Once the arc discharge is initiated, the power supply 20 operates to provide current pulses to the cathode and anode at a predetermined, adjustable frequency. In a preferred embodiment, the power supply 20 is a commercially available welding power supply which can generate current pulses between the cathode (the target) and the anode (the chamber) with independent control of starting current (150-530 A), background current (10-300 A), peak pulse current (100-400 A), pulse width (1-5 ms) and pulse frequency (20-300 Hz). As more fully explained below, the power supply can be operated in a continuous pulsed mode or a discontinuous pulsed mode. In the discontinuous pulsed mode, the power supply supplies high current pulses without a DC current component, and the arc discharge needs to be re-initiated between each pulse.

In a preferred embodiment, the power supply 20 is operated in a continuous pulsed mode wherein high current pulses are superimposed on a low DC background current component that is applied between the cathode and the anode. A typical waveform of the arc discharge is illustrated in FIG. 2 during operation in the continuous pulsed mode. The high current pulses achieve the primary deposition of the ionized species in the plasma (silicon ions, and the dopant or Al or other ions) on the substrate 12. The continuous pulsed mode has the advantage of simple, independent control of the pulsing parameters, as is compatible with a simple arc initiator such as the graphite trigger described above.

In general, it was found that the cathode spots run well on the fresh silicon targets but tended to move sluggishly with further target erosion, due to surface conditions such as roughness and contamination of the targets. After several depositions, the surface of the silicon targets became rough and inhomogeneous due to the melting and resolidification of the silicon.

Further, generally, the cathode spots are relatively stationary for the silicon targets as compared to the use of metal targets. Thus, the steering mechanism 28 that is placed behind the target and can include permanent magnets should produce a relatively strong magnetic field. For example, in one embodiment, the maximum radial and normal components of the magnetic flux densities on the cathode surface were approximately 2.0 mT and 3.5 mT, respectively (as measured with a gauss meter). The steering mechanism 28 operates to steer the cathode spots in the −J×B retrograde direction in order to achieve homogenous erosion of the target and to reduce the emission of macro-droplets from the target. The design of the system 10 should also consider the self magnetic field generated by the current flow within the cathode during operation, as this current is dependent on the parameters of the power supplied (such as magnitude of the current) and the size of the target.

In a continuous pulsed mode, the arc eventually quenches. The arc lifetime is connected with the number of new cathode spots produced and it increases with the arc current. Apart from the current, the average arc lifetime is a complex function of the target surface state, surface temperature, type of material used for the target, the external circuits, electrode geometry and external magnetic field. In any event, it is necessary to re-initiate the arc discharge as necessary. Using the parameters in the table below to control the arc, it was found that the lifetimes of the arc discharge were relatively short and varied from tens of milliseconds to a few seconds, depending strongly on the arc current and target surface conditions. However, once the silicon arc cathode spot is fixed on the target near its center, then the arc discharge was quite stable and long, but the target could become severely eroded with deep holes in the center.

In one embodiment, the trigger circuit 26 operates to provide a trigger pulse at a predetermined frequency in order to re-initiate the arc at that predetermined frequency. For example, in one embodiment, the arc is re-initiated every 1.5 seconds. The highest repetition rate of retriggering is limited by the heat accumulation in the trigger circuit 26.

Samples of thin film layers were prepared using a doped silicon target having a resistivity of approximately 0.005 ω-cm and a diameter of 76 mm and a thickness of 3 mm thick. The substrate for the samples was a p-type -type (111) silicon wafer having a resistivity of approximately 5.24 ω-cm, and this substrate was grounded. The power supply 20 was operated in the continuous pulsed mode, with the magnitude of the current pulses adjustable up to a peak magnitude of 400 Amps, the DC background current component adjustable between 20-30 A, the frequency of the applied pulses adjustable to 300 Hz, and the duration of a pulse adjustable from 1 to 2 msec. Specifically, the deposition parameters for the preparation the four samples are included in the following table:

| | | | Fre- | Pulse | | | Deposit |
|---|---|---|---|---|---|---|---|
| | Iₚₑₐₖ | I_{background} | quency | Width | Iₐᵥ | Time | Rate |
| Sample | (A) | (A) | (sec⁻¹) | (msec) | (A) | (sec) | (nm/sec) |
| A | 100 | 20 | 300 | 2.0 | 68 | 25 | 16 |
| B | 200 | 30 | 300 | 2.0 | 132 | 53 | 32 |
| C | 330 | 30 | 300 | 1.0 | 120 | 23 | 34 |
| D | 400 | 25 | 300 | 1.6 | 210 | 26 | 75 |

This table also illustrates that the deposition rate of the silicon layer is a function of the average arc current (Iₐᵥ), and is approximately 0.2 nm/A sec.

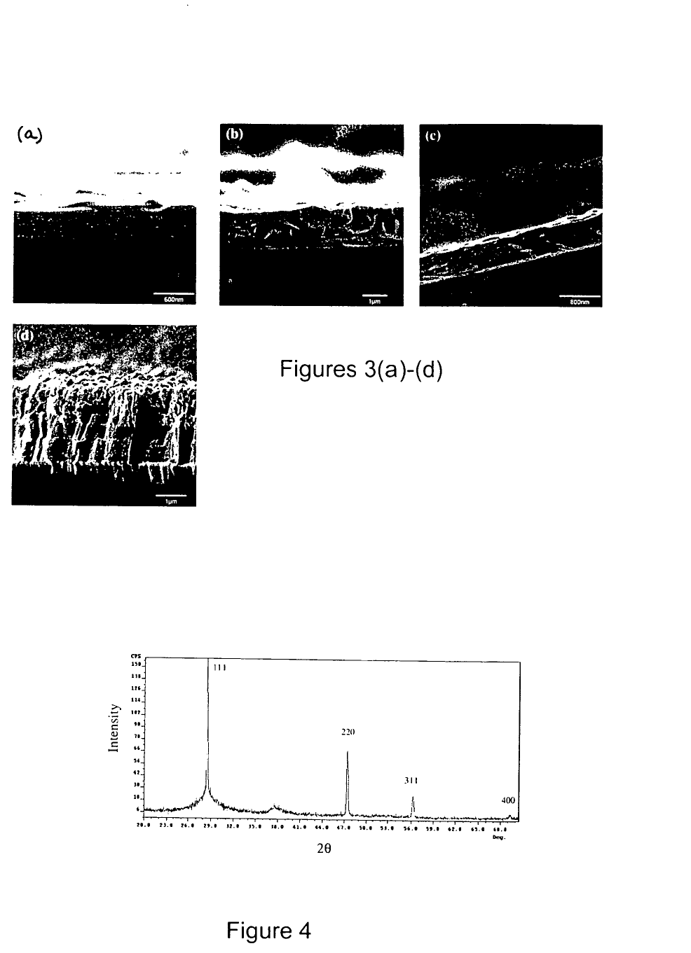

The deposited thin film layers of the prepared samples A, B, C, and D were subsequently analyzed. In particular, FIGS. 3(a)-(d) illustrate cross-sectional scanning electron microscope (SEM) micrographs of these four sample deposited silicon films (layers). Specifically, these silicon films exhibit a very dense microstructure without the columnar feature typical of sputtering and chemical vapor deposition at high deposition rates. Because the arc discharge is not filtered in the system 10 used to deposit these films, it is believed that the deposited films include macro-droplets that are polycrystalline silicon embedded in an amorphous silicon matrix. Specifically, an X-ray diffraction pattern of a typical sample silicon film is illustrated in FIG. 4, and shows a diffused peak at 2(θ)=28 degrees, which corresponds to the first halo of amorphous silicon. The superimposed sharp peaks are indexed to the (111), (220), (311) and (400) diffractions of polycrystalline silicon, respectively. Thus, it is believed that the contribution of the polycrystalline phase is due to the existence of macro-droplets that melted on the cathode and later solidified on the substrate 12.

The kinetic energy of the ions of cathode material impinging on the substrate and the number of macro-droplets are determined directly by the power density at the cathode spots, which is primarily determined by the amplitude of applied current. The adhesion of the film to the substrate is not as good for the sample prepared with the peak current of 100 A, as evidenced by the existence of a micro gap at the interface. But the sample film prepared with a high peak current of 400 A resulted in a substantial increase in the roughness of the film and also a decrease in the film density as compared to the other samples. Damage to the silicon substrate is shown by large cracks perpendicular to the interface, which may be indicative of induced film stress. Higher quality silicon films were obtained in the samples prepared using the moderate current values of 200 A and 330 A.

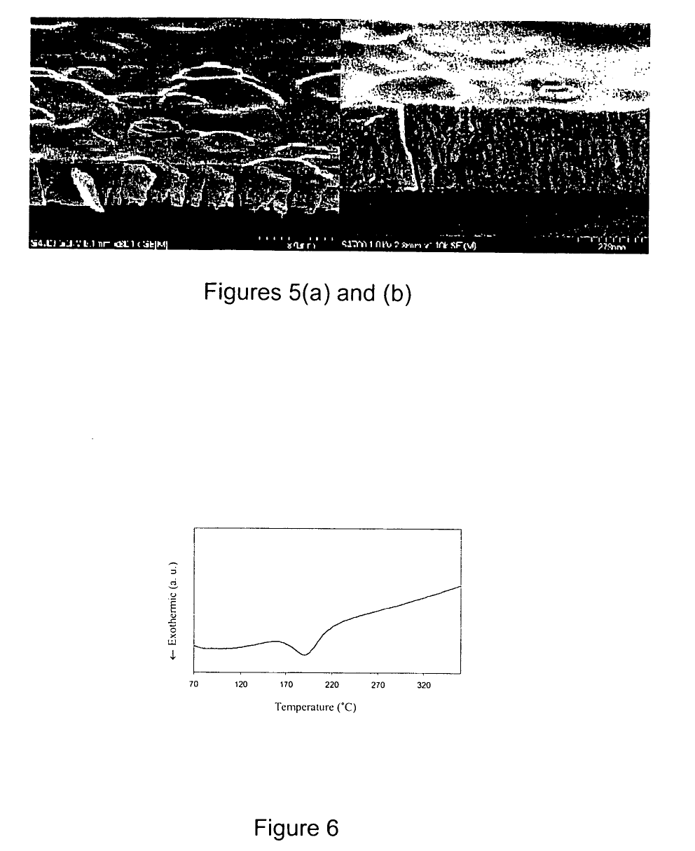

As another example, a doped silicon thin film is deposited using the continuous pulsed mode, a highly doped silicon target, such as the target used in the previous examples, and deposition parameters including a 100 A peak current, 100 pulses/second, a 2 msec pulse width, and an 18 second duration. FIG. 5(a) illustrates a cross-sectional SEM view of the thin film deposited using these parameters.

As a further example, a silicon composite thin film is deposited using the continuous pulsed mode, a Si—Al composite target (3:1 ratio of Si to Al by weight), and deposition parameters including a 150 A peak current, 60 pulses/sec, a 2 msec pulse width, and a 64 second duration. FIG. 5(b) illustrates a cross-sectional SEM view of the thin film deposited using these parameters. With respect to this thin film, its composition is silicon based but with a higher Al content than the composition of the target, due to the lower melting point of the aluminum compared to the silicon. Also, the crystallization temperature of the deposited amorphous film is decreased to as low as 192 degrees C., as illustrated in FIG. 6, which shows a differential scanning calorimetry curve for the deposited Si:Al film. This film is also amorphous.

The cathodic vacuum arc deposition system and process as described above can be used to deposit silicon layers to a desired thickness, preferentially from hundreds of nanometers to several microns and perhaps greater. The pulsed cathodic arc process described above is advantageous, in that it provides a high deposition rate, is a low temperature, relatively low cost, and high energy process.

A new trend for MEMS devices and structures uses thicker (i.e., greater than 10 microns) structural layers because there are advantages to such films in certain applications. For example, the mass of any inertial device will be increased by the added thickness, allowing for smaller lateral dimensions and increased device density, and thus greater yield and lower cost. Thicker films also exhibit greater strength and stiffness. In addition, an increased sidewall area results in lateral electric fields and capacitances, enhancing performance and sensitivity. To realize such thick films, the pulsed cathodic arc process is advantageous.

Various other features and advantages of the invention are set forth in the following claims.

1. A method of depositing a silicon layer on a substrate as a component in a micro-system, the method comprising:
placing a doped silicon target and a substrate in a chamber;
creating a vacuum in the chamber;
initiating an arc discharge using the silicon target as a cathode and the chamber as an anode to generate a plasma containing target material at a cathode spot on the silicon target, wherein the plasma extends between the silicon target and the substrate and the cathode spot changes location over time;
applying current pulses of a predetermined frequency between the cathode and the anode; and
reinitiating the arc as necessary so that silicon material from the plasma is deposited on the substrate to form a layer having a desired thickness.

2. The method of claim 1, wherein the current pulses are superimposed on a DC current component.

3. The method of claim 1, further including steering the cathode spot on the silicon target.

4. The method of claim 1, further including using a cooling assembly to maintain the temperature of the silicon target below a predetermined threshold.

5. The method of claim 1, wherein the silicon target is doped with a dopant having a concentration in excess of 1×10²⁰ atoms/cm³.

6. The method of claim 1, wherein the substrate remains at a temperature below 500° C. during the deposition.

7. The method of claim 1, wherein the arc is initiated using a ceramic tube coated with graphite and initiation of the arc is based on explosive destruction of the graphite layer and cathode interface caused by rapid joule heating.

8. The method of claim 1, wherein the magnitude of the current pulses is adjustable up to a peak magnitude of 400 Amps.

9. The method of claim 1, wherein the predetermined frequency of the applied pulses is adjustable to 300 Hz.

10. The method of claim 1, wherein the duration of a pulse is adjustable from one to five milliseconds.

11. The method of claim 1, wherein the deposition rate is greater than 16 nm/sec.

12. The method of claim 1, wherein the arc is reinitiated at a predetermined frequency.

13. A method of depositing a silicon composite layer on a substrate, the method comprising:
placing a silicon composite target and a substrate in a chamber;
creating a vacuum in the chamber;
initiating an arc discharge using the silicon composite target as a cathode and the chamber as an anode to generate a plasma at a cathode spot on the silicon composite target, wherein the plasma extends between the target and the substrate and the cathode spot changes location over time;
applying current pulses of a predetermined frequency between the cathode and the anode; and
reinitiating the arc as necessary so that silicon material from the plasma is deposited on the substrate to form a silicon composite layer having a desired thickness.

14. The method of claim 13, wherein the current pulses are superimposed on a DC current component.

15. The method of claim 13, further including steering the cathode spot on the silicon composite target.

16. The method of claim 13, further including using a cooling assembly to maintain the temperature of the silicon composite target below a predetermined threshold.

17. The method of claim 13, wherein the silicon composite target incorporates one or aluminum or titanium.

18. The method of claim 13, wherein the substrate remains at a temperature below 500° C. during the deposition.

19. The method of claim 13, wherein the arc is initiated using a ceramic tube coated with graphite and initiation of the arc is based on explosive destruction of the graphite layer and cathode interface caused by joule heating.

20. The method of claim 13, wherein the magnitude of the current pulses is adjustable up to a peak magnitude of 400 Amps.

21. The method of claim 13, wherein the predetermined frequency of the applied pulses is adjustable to 300 Hz.

22. The method of claim 13, wherein the duration of a pulse is adjustable from one to five milliseconds.

23. The method of claim 13, wherein the arc is reinitiated at a predetermined frequency.
